(19) United States
(12) Patent Application Publication
(10) Pub. No.: US 2025/0118247 A1
(43) Pub. Date: Apr. 10, 2025

(54) PIXEL AND DISPLAY DEVICE INCLUDING THE SAME

(71) Applicant: SAMSUNG DISPLAY CO., LTD., YONGIN-SI (KR)

(72) Inventors: SE HYUN LEE, Yongin-si (KR); KWI HYUN KIM, Yongin-si (KR); JIN JOO HA, Yongin-si (KR)

(21) Appl. No.: 18/820,528

(22) Filed: Aug. 30, 2024

(30) Foreign Application Priority Data
Oct. 5, 2023 (KR) 10-2023-0132618

(51) Int. Cl. G09G 3/32

(52) U.S. Cl. CPC G09G 3/32; G09G 2300/0426

(57) ABSTRACT

A pixel includes a first transistor having a first electrode connected to a first node, a second electrode connected to a second node, and a gate electrode connected to a third node. The pixel further includes second and third transistors and first and second capacitors. The second transistor is connected between a data line and the third node and has a gate electrode electrically connected to a first scan line. The third transistor is connected between a first power source line connected to a first driving power source and the first node, and has a gate electrode electrically connected to an emission control line. The first capacitor is connected between the first node and the third node, and the second capacitor is connected between the second node and the third node. A light emitting element is connected between the second node and a second power source line.

### CROSS-REFERENCE TO RELATED APPLICATION

The application claims priority to and the benefit of Korean Patent Application No. 10-2023-0132618, filed Oct. 5, 2023, which is hereby incorporated by reference for all purposes as if fully set forth herein.

### BACKGROUND

### 1. Field

One or more embodiments disclosed herein relate to a pixel and a display device including the same.

### 2. Discussion

A variety of display devices have been developed. Examples include liquid crystal display devices and organic light emitting display devices.

Recently, head-mounted display devices (HMDs) have been developed. A head-mounted display device is worn by a user in the form of glasses or a helmet and may be used to implement virtual reality (VR) or augmented reality (AR). In VR or AR, focus is formed at a close distance in front of the eyes of the user. A high-resolution panel can be applied to the head-mounted display device. Accordingly, pixels that can be applied to the high-resolution panel may be used.

### SUMMARY

An object of the present invention is to provide a pixel which may be suitable for use in a high-resolution panel and a display device including the same.

Another object of the present invention is to provide a pixel as mentioned above which has a driving transistor that includes a body electrode.

Another object of the present invention is to maintain a constant amount of current flowing through the driving electrode in spite of changes in voltage that take place at nodes coupled to the driving electrodes.

Another object of the present invention is to achieve the aforementioned objects by compensating for changes in threshold voltage of a driving transistor of the pixel.

Another object of the present invention is to provide a display panel which uses the aforementioned type of pixels for an AR or VR application.

A pixel according to embodiments of the present invention may include a first transistor having a first electrode connected to a first node, a second electrode connected to a second node, and a gate electrode connected to a third node; a second transistor connected between a data line and the third node and having a gate electrode electrically connected to a first scan line; a third transistor connected between a first power source line to which a voltage of a first driving power source is supplied and the first node, and having a gate electrode electrically connected to an emission control line; a first capacitor connected between the first node and the third node; a second capacitor connected between the second node and the third node; and a light emitting element connected between the second node and a second power source line to which a second driving power source is supplied.

The pixel may further include a fourth transistor having a first electrode connected to the second node, a second electrode electrically connected to a third power source line to which an initialization power source is supplied, and a gate electrode electrically connected to a second scan line.

The light emitting element may be turned off when a voltage of the initialization power source is supplied to the second node.

Each of the first to fourth transistors may be a MOSFET including a body electrode.

Each of the first to fourth transistors may be an N-type transistor.

A ground voltage may be supplied to the body electrode of each of the first to fourth transistors.

One horizontal period may include a first period and a second period. During the first period, the fourth transistor may be set to a turned-on state, and the second and third transistor may be set to a turned-off state. During the second period after the first period, the second transistor may be set to a turned-on state, and the third and fourth transistors may be set to a turned-off state.

A voltage of a data signal may be supplied to the data line during the first and second periods.

The horizontal period may further include a third period. During the third period after the second period, the second and third transistors may be set in a turned-on state, and the fourth transistor may be set to the turned-off state.

A display device according to embodiments of the present invention may include pixels connected to writing scan lines, initialization scan lines, data lines, and emission control lines. A pixel located in an i-th pixel row (i is an integer greater than 0) and a j-th pixel column (j is an integer greater than 0) may include a first transistor having a first electrode connected to a first node, a second electrode connected to a second node, and a gate electrode connected to a third node; a second transistor connected between a j-th data line among the data lines and the third node, and turned on when a first scan signal is supplied to a first scan line among the writing scan lines; a third transistor connected between a first power source line to which a voltage of a first driving power source is supplied and the first node, and turned on when an emission control signal is supplied to a k-th emission control line (k is an integer greater than 0); a first capacitor connected between the first node and the third node; a second capacitor connected between the second node and the third node; and a light emitting element connected between the second node and a second power source line to which a second driving power source is supplied.

The pixel located in the i-th pixel row and the j-th pixel column may further include a fourth transistor having a first electrode connected to the second node, a second electrode electrically connected to a third power source line to which an initialization power source is supplied, and turned on when a second scan signal is supplied to a second scan line.

Each of the first to fourth transistors may be a MOSFET including a body electrode, and a ground voltage may be supplied to the body electrode.

Each of the first to fourth transistors may be an N-type transistor.

In accordance with one or more additional embodiments, a pixel includes a driving transistor connected between first and second nodes; a first capacitor electrically connected between the first node and a gate of the driving transistor; a second capacitor electrically connected between the second node and the gate of the driving transistor, wherein: the gate of the driving transistor is coupled to a third node connected between the first capacitor and the second capacitor, the first capacitor is configured to transmit an amount of voltage change at the first node to the third node, and the second capacitor is configured to transmit an amount of voltage change at the second node to the third node. The driving transistor may include a body electrode. The body electrode may be coupled to a reference potential, which, for example, may be a ground voltage or different from a ground voltage.

The amount of voltage change at the first node may correspond to a difference in voltage of the first node that takes place between a data signal writing period of the pixel and an emission period of the pixel, and the amount of voltage change at the second node may correspond to a difference in voltage of the second node that takes place between the data signal writing period and the emission period of the pixel.

A voltage of the third node may be compensated by the voltage change at the first node and the voltage change at the second node to maintain flow of a constant current from the first node to the second node during the signal writing period and the emission period of the pixel.

The pixel may further include an emission transistor connected to the first node, and an initialization transistor connected to the second node, wherein each of the emission transistor and the initialization transistor includes a body electrode. The emission transistor may be connected to a first voltage source, and the initialization transistor may be coupled to a second voltage source.

### BRIEF DESCRIPTION OF THE DRAWINGS

The accompanying drawings, which are included to provide a further understanding of the inventive concepts, and are incorporated in and constitute a part of this specification, illustrate exemplary embodiments of the inventive concepts, and, together with the description, serve to explain principles of the inventive concepts.

FIG. 1 is a diagram illustrating a transistor according to an embodiment of the present invention.

FIG. 2 is a block diagram illustrating a display device according to an embodiment of the present invention.

FIG. 3 is a block diagram illustrating an embodiment of a scan driver, a data driver, and a power supply shown in FIG. 2.

FIG. 4 is a circuit diagram illustrating an embodiment of the pixel shown in FIG. 2.

FIG. 5 is a waveform diagram illustrating an embodiment of a method for driving the pixel shown in FIG. 4.

FIGS. 6 to 8 are circuit diagrams illustrating embodiments of an operation process of the pixel according to signals of FIG. 5.

FIG. 9 is a waveform diagram illustrating an embodiment of the method for driving the pixel shown in FIG. 4.

### DETAILED DESCRIPTION OF THE ILLUSTRATED EMBODIMENTS

Hereinafter, various embodiments of the present invention will be described in detail with reference to the accompanying drawings so that those of ordinary skill in the art may easily implement the present invention. The present invention may be embodied in various different forms and is not limited to the embodiments described herein.

In order to clearly describe the present invention, parts that are not related to the description are omitted from the drawings, and the same or similar components are denoted by the same reference numerals throughout the specification.

Throughout the specification, when a first part is said to be “connected or coupled” to a second part, this includes not only a case where the first part and the second part are “directly connected or coupled”, but also a case where they are “indirectly connected or coupled” by another element interposed therebetween. Terms used herein are for describing specific embodiments and are not intended to limit the present disclosure. Throughout the specification, when a part includes a certain component, unless the context clearly indicates otherwise, this means that it may further include other components rather than excluding other components. At least one of X, Y, and Z, and at least one selected from the group consisting of X, Y, and Z may be construed as one X, one Y, one Z, or any combination of two or more of X, Y, and Z (for example, XYZ, XYY, YZ, and ZZ). As used herein, the term “and/or” may include any combination of one or more of the corresponding elements.

Although the terms “first”, “second”, etc. may be used herein to describe various elements, these elements should not be limited by these terms. These terms are only used to distinguish one element from another element. Thus, a first element discussed below could be termed a second element without departing from the scope of the present disclosure.

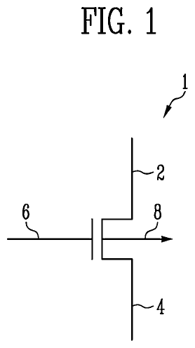

FIG. 1 is a diagram illustrating a transistor 1 according to an embodiment of the present invention.

Referring to FIG. 1, the transistor 1 may include a first electrode 2, a second electrode 4, a gate electrode 6, and a body electrode 8. For example, the transistor 1 may be a MOSFET (Metal-Oxide-Semiconductor Field-Effect Transistor). The transistor 1 (for example, MOSFET) including the body electrode 8 has a small mounting area (e.g., consumes a smaller amount of space than a MOSFET which does not have a body electrode) and therefore may be suitable for implementing a high-resolution pixel, e.g., a pixel suitable for use in high-resolution display panel.

The transistor 1 may be formed, for example, on a silicon wafer. In one embodiment, a panel can be implemented by stacking a transistor layer, a light emitting layer, a cover layer, and the like on the silicon wafer. However, this is only an example, and the transistor 1 may be formed on various substrates (for example, a glass substrate).

The first electrode 2 of the transistor 1 may be a drain electrode (or source electrode), and the second electrode 4 of the transistor 1 may be a source electrode (or drain electrode). Since the transistor 1 includes the body electrode 8, a threshold voltage of the transistor 1 may be changed due to a body effect. The body effect may include the case where the threshold voltage of the transistor 1 changes due to a voltage difference between the body electrode 8 and the source electrode (or the second electrode 4) of the transistor 1.

For example, when a voltage level of the source electrode 4 is higher than a voltage level of the body electrode 8, the threshold voltage may increase. When the threshold voltage of the transistor 1 changes, the magnitude of a current flowing from the drain electrode 2 to the source electrode 4 of the transistor 1 may change, which may have an adverse effect on operation of the pixel. As will be described in greater detail below, changes in the threshold voltage may be compensated to provide a constant current flowing from the drain electrode 2 to the source electrode 4.

In order to keep the magnitude of the current flowing from the drain electrode 2 to the source electrode 4 of the transistor 1 constant, the threshold voltage of the transistor 1 may be compensated in accordance with embodiments described herein by reflecting changes in voltage that take place at nodes electrically connected to the drain electrode 2 and source electrode 4 in the node coupled to the gate of the transistor 1. An embodiment of the present invention, thus, proposes a pixel in which the transistor 1 including the body electrode 8 is used as a driving transistor and the threshold voltage can be compensated. For example, the pixel according to an embodiment of the present invention may reflect the voltage change at the drain electrode 2 and the voltage change at the source electrode 4 to the gate electrode 6, so that the magnitude of the current flowing from the drain electrode 2 to the source electrode 4 remains constant even if the threshold voltage changes.

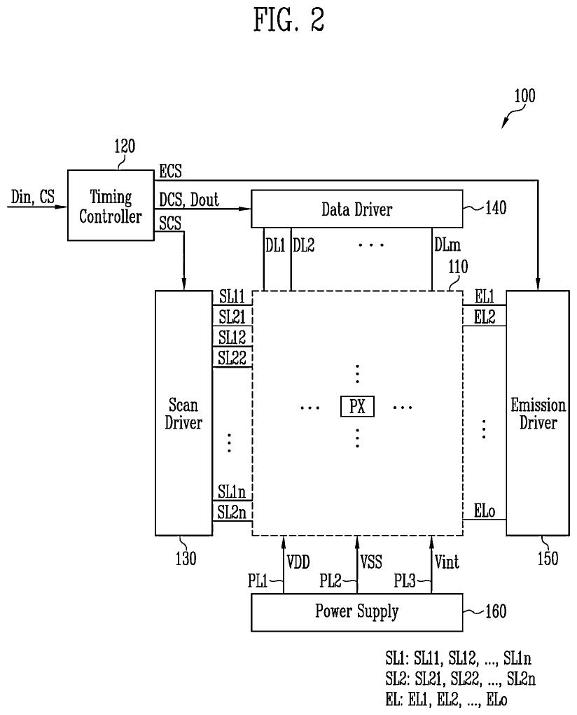

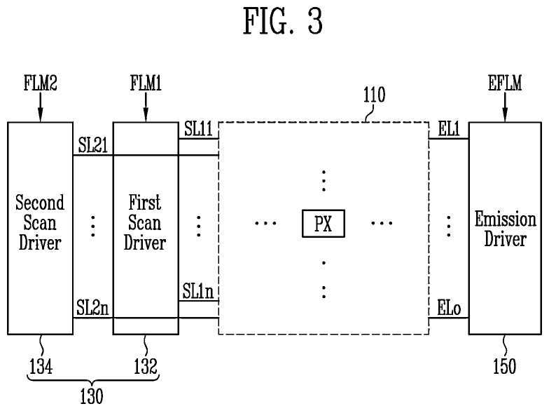

FIG. 2 is a block diagram illustrating a display device 100 according to an embodiment of the present invention. FIG. 3 is a block diagram illustrating an embodiment of a scan driver, a data driver, and a power supply shown in FIG. 2.

Referring to FIG. 2, the display device 100 according to an embodiment of the present invention may include a pixel unit 110 (or panel), a timing controller 120, a scan driver 130, a data driver 140, an emission driver 150, and a power supply 160. The above components may be implemented as separate integrated circuits, and two or more of the above components may be integrated and implemented as one integrated circuit. In addition, the scan driver 130 and/or the emission driver 160 may be formed in the pixel unit 110.

The pixel unit 110 may include pixels PX connected to writing scan lines SL11 to SL1n, initialization scan lines SL21 to SL2n, data lines DL1 to DLm, emission control lines EL1 to ELo, and power source lines PL1, PL2, and PL3, where n, m, and o may be integers greater than 0.

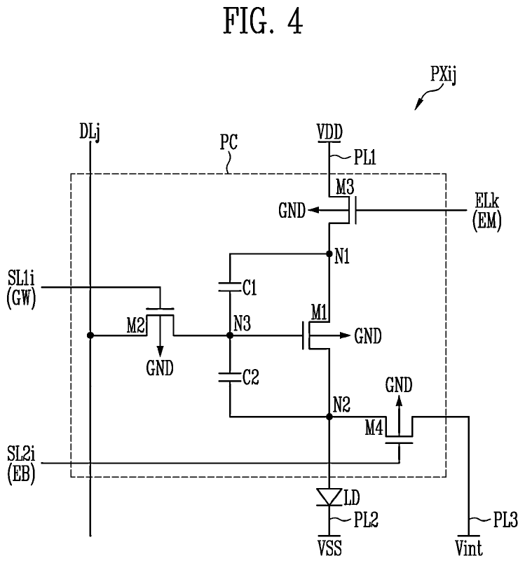

For example, a representative pixel PXij (e.g., see FIG. 4) located on an i-th horizontal line (or pixel row) and a j-th vertical line (or pixel column) may be connected to an i-th writing scan line SL1i, an i-th initialization scan line SL2i, a k-th emission control line Elk, and a j-th data line DLj, where i may be an integer smaller than n, j may be an integer smaller than m, and k may be an integer smaller than o. Here, k may be a number equal to or smaller than i. For example, when each of the emission control lines EL1 to ELo is connected to pixels PX located on one horizontal line, k may be the same number as i. For example, when each of the emission control lines EL1 to ELo is connected to pixels PX located on two or more horizontal lines, k may be a number smaller than i.

When a first scan signal is supplied to each of the writing scan lines SL11 to SL1n, pixels PX may be selected in units of horizontal lines (for example, pixels PX connected to the same scan line may be classified into one horizontal line (or pixel row)). The pixels PX selected by the first scan signal may receive data signals from corresponding data lines (DL1 to DLm) connected to the pixels. The pixels PX that receive the data signals may generate light with predetermined luminances based on the voltages of the data signals.

The timing controller 120 may receive input data Din and a control signal CS from a host system through an interface. For example, the timing controller 120 may receive the input data Din and the control signal CS from at least one of a graphics processing unit (GPU), a central processing unit (CPU), or an application processor (AP) included in the host system. The control signal CS may include various signals including a clock signal.

The timing controller 120 may generate a scan driving signal SCS, a data driving signal DCS, and an emission driving signal ECS based on the control signal CS. The scan driving signal SCS, the data driving signal DCS, and the emission driving signal ECS may be supplied to the scan driver 130, the data driver 140, and the emission driver 150, respectively.

The timing controller 120 may rearrange the input data Din to match the specifications of the display device 100. For example, the timing controller 120 may correct the input data Din to generate output data Dout and supply the output data Dout to the data driver 140. In an embodiment, the timing controller 120 may correct the input data Din in response to optical measurement results measured during a process.

The scan driver 130 may receive the scan driving signal SCS from the timing controller 120. The scan driving signal SCS may include at least one scan start signal and clock signals to drive the scan driver 130. The scan driver 130 may generate a first scan signal and a second scan signal by shifting the scan start signal in response to a clock signal.

To this end, the scan driver 130 may include a first scan driver 132 and a second scan driver 134 as shown in FIG. 3. The first scan driver 132 may receive a first scan start signal FLM1 and generate the first scan signal by shifting the first scan start signal FLM1 in response to a clock signal. The first scan driver 132 may sequentially supply the first scan signal to the writing scan lines SL11 to SL1n.

The second scan driver 134 may receive a second scan start signal FLM2 and generate the second scan signal by shifting the second scan start signal FLM2 in response to a clock signal. The second scan driver 134 may sequentially supply the second scan signal to the initialization scan lines SL21 to SL2n. The first scan signal and the second scan signal may be set to a gate-on voltage so that the transistors included in the pixels PX can be turned on.

For example, the first and second scan signals having a low level may be supplied to a P-type transistor, and the first and second scan signals having a high level may be supplied to an N-type transistor. A transistor supplied with the first scan signal or the second scan signal may be turned on in response to the first scan signal or the second scan signal. Hereinafter, the expression that the first scan signal and the second scan signal are supplied may include the case where the gate-on voltage is supplied to the writing scan line SL1 and the initialization scan line SL2. Also, the expression that the first scan signal and the second scan signal are not supplied may include the case where a gate-off voltage is supplied to the writing scan line SL1 and the initialization scan line SL2.

FIG. 3 shows the first scan driver 132 and the second scan driver 134 connected to the writing scan line SL1 and the initialization scan line SL2, respectively. However, embodiments of the present invention are not limited thereto. For example, the writing scan line SL1 and the initialization scan line SL2 may be driven by one scan driver.

The data driver 140 may receive the output data Dout and the data driving signal DCS from the timing controller 120. The data driving signal DCS may include a sampling signal and/or timing signals to drive the data driver 140.

The data driver 140 may generate data signals based on the data driving signal DCS and corresponding output data Dout. For example, the data driver 140 may generate an analog data signal based on a grayscale of the output data Dout.

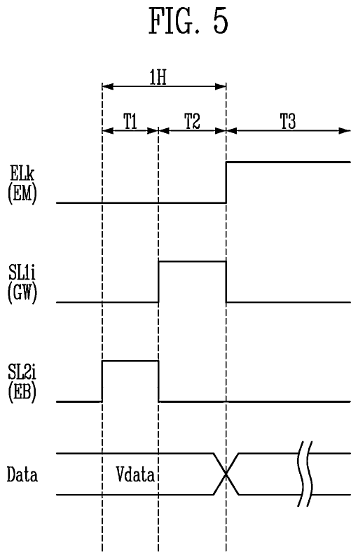

The data driver 140 may apply a constant voltage to the data lines DL1 to DLm based on the generated analog data signal. For example, referring to FIG. 5, the data driver 140 may supply a voltage Vdata of the data signal to the data lines DL1 to DLm for one horizontal period 1H (e.g., see FIG. 5).

The power supply 160 may generate various power sources to drive the display device 100. For example, the power supply 160 may generate a first driving power source VDD, a second driving power source VSS, and an initialization power source Vint. The first driving power source VDD may be used to supply driving current to the pixels PX. The second driving power source VSS may receive driving current from the pixels PX (e.g., see FIG. 4). During a period in which the pixels PX are set to emit light, the first driving power source VDD may be set to a higher voltage than the second driving power source VSS.

The initialization power source Vint may be a voltage that initializes the first electrode (or anode electrode) of a light emitting element LD (see FIG. 4) included in each of the pixels PX. The initialization power source Vint may correspond to a voltage value which turns the light emitting element LD off when the initialization power source Vint is supplied to the first electrode of the light emitting element LD.

The first driving power source VDD generated by the power supply 160 may be supplied to a first power source line PL1, the second driving power source VSS generated by the power supply 160 may be supplied to a second power source line PL2, and the initialization power source Vint generated by the power supply 160 may be supplied to a third power source line PL3. The first power source line PL1, the second power source line PL2, and the third power source line PL3 may be commonly connected to the pixels PX, but embodiments of the present invention are not limited thereto.

In an embodiment, the first power source line PL1 may include a plurality of power source lines, and the plurality of power source lines may be connected to different pixels PX. In an embodiment, the second power source line PL2 may include a plurality of power source lines connected to different pixels PX. In an embodiment, the third power source line PL3 may include a plurality of power source lines connected to different pixels PX. In an embodiment of the present invention, the pixels PX may be connected to one of the first power source lines PL1, one of the second power source lines PL2, and one of the third power source lines PL3.

The emission driver 150 may receive the emission driving signal ECS from the timing controller 120. The emission driving signal ECS may include an emission start signal and clock signals to drive the emission driver 150. The emission driver 150 may generate an emission control signal while shifting the emission start signal EFLM in response to a clock signal. The emission driver 150 may sequentially supply the emission control signal to the emission control lines EL1 to ELo. The emission control signal may be set to a gate-on voltage so that corresponding transistors in the pixels PX can be turned on.

For example, the emission control signal having a low level may be supplied to a P-type transistor, and the emission control signal having a high level may be supplied to an N-type transistor. A transistor that receives the emission control signal may be turned on in response to the emission control signal. Hereinafter, the expression that the emission control signal is supplied may include the case where the gate-on voltage is supplied to the emission control line EL. Also, the expression that the emission control signal is not supplied may include the case where a gate-off voltage is supplied to the emission control line EL.

FIG. 4 is a circuit diagram illustrating an embodiment of the pixel PX shown in FIG. 2. FIG. 4 shows the pixel PX located on the i-th horizontal line and the j-th vertical line, and therefore may be labeled PXij.

Referring to FIG. 4, the pixel PXij according to an embodiment of the present invention may be connected to corresponding signal lines SL1i, SL2i, ELk, and DLj. For example, the pixel PXij may be connected to the i-th writing scan line SL1i, the i-th initialization scan line SL2i, the k-th emission control line ELk, and the j-th data line DLj. In an embodiment, the pixel PXij may be further connected to the first power source line PL1, the second power source line PL2, and the third power source line PL3.

The pixel PXij according to an embodiment of the present invention may include the light emitting element LD and a pixel circuit PC for controlling the amount of current supplied to the light emitting element LD.

The light emitting element (e.g., a light emitting diode) LD may be connected between the first power source line PL1 and the second power source line PL2 through the pixel circuit PC. For example, the first electrode (or anode electrode) of the light emitting element LD may be electrically connected to the first power source line PL1 via a second node N2, a first transistor M1, a first node N1, and a third transistor M3 of the pixel circuit PC. The second electrode (or cathode electrode) of the light emitting element LD may be electrically connected to the second power source line PL2. The light emitting element LD may generate light with a predetermined luminance in response to the amount of current supplied from the first power source line PL1 to the second power source line PL2 via the pixel circuit PC.

The light emitting element LD may be, for example, an organic light emitting diode. In other embodiments, the light emitting element LD may be an inorganic light emitting diode, such as a micro LED (light emitting diode) or a quantum dot light emitting diode. In other embodiments, the light emitting element LD may be an element which includes a combination of organic and inorganic materials. FIG. 4 shows the pixel PXij including a single light emitting element LD. However, in another embodiment, the pixel PXij may include a plurality of light emitting elements LD, and the plurality of light emitting elements LD may be connected in series, in parallel, or in series and parallel.

The pixel circuit PC may include a first transistor M1, a second transistor M2, a third transistor M3, a fourth transistor M4, a first capacitor C1, and a second capacitor C2. Each of the first to fourth transistors M1 to M4 may include a body electrode. For example, each of the first to fourth transistors M1 to M4 may be a metal oxide semiconductor field effect transistor (MOSFET) including a body electrode. In this case, the first to fourth transistors M1 to M4 may be mounted in a small area. Accordingly, the pixel PXij may be suitable for use in a high-resolution panel. Body electrodes of the first to fourth transistors M1 to M4 may be supplied with a predetermined potential, e.g., ground voltage GND. The ground voltage GND may have a different (e.g., higher) voltage level than the second driving power source VSS.

In an embodiment, the second driving power source VSS may be provided as the ground voltage GND. In this case, the body electrodes of the first to fourth transistors M1 to M4 may be electrically connected to the second power source line PL2. In an embodiment, each of the first to fourth transistors M1 to M4 may be formed as an N-type transistor.

A first electrode of the first transistor (driving transistor) M1 may be connected to the first node N1, and a second electrode of the first transistor M1 may be connected to the second node N2. Here, the term ‘connected’ may include the meaning of being electrically connected. A gate electrode of the first transistor M1 may be connected to a third node N3. The first node N1 may refer to a node to which a second electrode of the third transistor M3 is connected, and the second node N2 may refer to a node to which the first electrode of the light emitting element LD is connected. The first transistor M1 may control the amount of current supplied from the first driving power source VDD to the second driving power source VSS, via the light emitting element LD, in response to a voltage of the third node N3.

The second transistor M2 may be connected between the data line DLj and the third node N3. In addition, a gate electrode of the second transistor M2 may be electrically connected to the i-th writing scan line SL1i. The second transistor M2 may be turned on when a first scan signal GW is supplied to the i-th writing scan line SL1i to electrically connect the data line DLj and the third node N3.

A first electrode of the third transistor M3 may be electrically connected to the first power source line PL1, and the second electrode of the third transistor M3 may be connected to the first node N1. In addition, a gate electrode of the third transistor M3 may be electrically connected to the emission control line ELk. The third transistor M3 may be turned on when the emission control signal is supplied to the emission control line ELk and may be turned off when the emission control signal is not supplied. When the third transistor M3 is turned off, electrical connection between the first power source line PL1 and the first node N1 may be blocked.

A first electrode of the fourth transistor M4 may be connected to the second node N2, and a second electrode of the fourth transistor M4 may be electrically connected to the third power source line PL3. In addition, a gate electrode of the fourth transistor M4 may be electrically connected to the i-th initialization scan line SL2i. The fourth transistor M4 may be turned on when a second scan signal EB is supplied to the i-th initialization scan line SL2i to electrically connect the second node N2 and the third power source line PL3.

The first capacitor C1 may be connected between the first node N1 and the third node N3. As discussed in greater detail below, the first capacitor C1 may transmit the amount of voltage change at the first node N1 to the third node N3.

The second capacitor C2 may be connected between the second node N2 and the third node N3. The second capacitor C2 may transmit the amount of voltage change at the second node N2 to the third node N3. The voltage change amounts transmitted by the first capacitor C1 and the second capacitor C2 may be used as a basis for compensating changes in threshold voltage of the driving transistor M1, resulting in a flow of constant current.

FIG. 5 is a waveform diagram illustrating an embodiment of a method for driving the pixel shown in FIG. 4.

Referring to FIGS. 2, 4, and 5, a horizontal period 1H (or a specific horizontal period) in which the data signal is supplied to the pixel PXij (located on the i-th horizontal line and the j-th vertical line) may be divided into a first period T1 and a second period T2. The start time point of the second period T2 may be equal to or after the end time point of the first period T1.

The data driver 140 may supply the voltage Vdata of the data signal to the data line DLj during the first period T1 and the second period T2.

The scan driver 130 (or the first scan driver 132) may supply the first scan signal GW to the i-th writing scan line SL1i during the second period T2.

The scan driver 130 (or the second scan driver 134) may supply the second scan signal EB to the i-th initialization scan line SL2i during the first period T1.

The emission driver 150 may supply an emission control signal EM to the emission control line ELk during a third period T3.

The first period T1 may be a period in which a voltage of the initialization power source Vint is supplied to the second node N2. During the first period T1, the anode electrode of the light emitting element LD may be initialized. For example, the second node N2 may be initialized during the first period T1. The first period T1 may therefore be referred to as an initialization period.

The second period T2 may be a period in which the voltage Vdata of the data signal is supplied to the third node N3. This second period T2 may therefore be referred to as a data signal writing period.

During the third period T3, the first transistor M1 may control the amount of current flowing from the first driving power source VDD to the second driving power source VSS, via the light emitting element LD, in response to a voltage of the third node N3 which has been adjusted to compensate the threshold voltage of transistor M1 as described herein. In this case, during the third period T3, the light emitting element LD may emit light with a luminance corresponding to the amount of current supplied from the first transistor M1. The third period T3 may therefore be referred to as an emission period.

In addition, since the first transistor M1 may operate in response to the voltage of the third node N3 (that reflects a voltage difference at the first node N1 between the second period T2 and the third period T3 and a voltage difference at the second node N2 between the second period T2 and the third period T3), a threshold voltage of the first transistor M1 may be compensated during the third period T3.

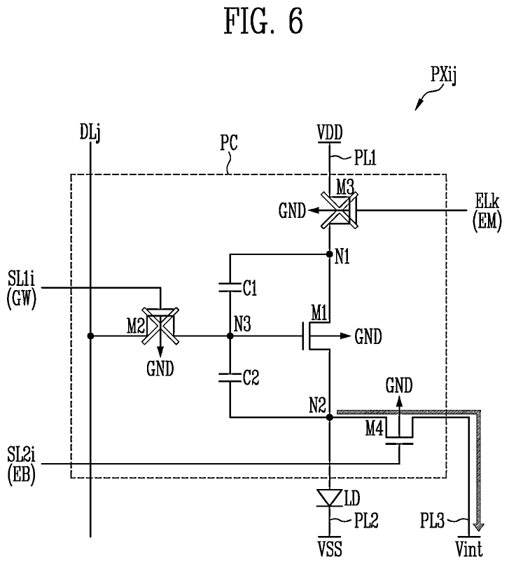

FIGS. 6 to 8 are circuit diagrams illustrating embodiments of an operation process of the pixel according to signals of FIG. 5. The pixel circuit PC of FIGS. 6 to 8 may correspond to the pixel circuit PC of FIG. 5.

Referring to FIG. 6, during the first period T1, the third transistor M3 may be turned off by the emission control signal EM supplied to the emission control line ELk. During the first period T1, the second transistor M2 may be turned off (as indicated by the “X” in FIG. 6) by the first scan signal GW supplied to the i-th writing scan line SL1i. During the first period T1, the fourth transistor M4 may be set to a turned-on state by the second scan signal EB supplied to the i-th initialization scan line SL2i.

When the second transistor M2 is turned off (indicated by the “X” in FIG. 6), electrical connection between the data line DLj and the third node N3 may be blocked. When the third transistor M3 is turned off, electrical connection between the first power source line PL1 and the first node N1 may be blocked.

When the fourth transistor M4 is turned on, the voltage of the initialization power source Vint may be supplied to the second node N2. When the voltage of the initialization power source Vint is supplied to the second node N2, the light emitting element LD may be initialized. For example, when the voltage of the initialization power source Vint is supplied, a parasitic capacitor of the light emitting element LD may be discharged. Here, the voltage of the initialization power source Vint may be set to a voltage at which the light emitting element LD is turned off (or does not emit light). Accordingly, the light emitting element LD may be set to a non-light emitting state.

In addition, when the voltage of the initialization power source Vint is supplied to the second node N2, a source electrode of the first transistor M1 may be set to a lower voltage than the body electrode of the first transistor M1.

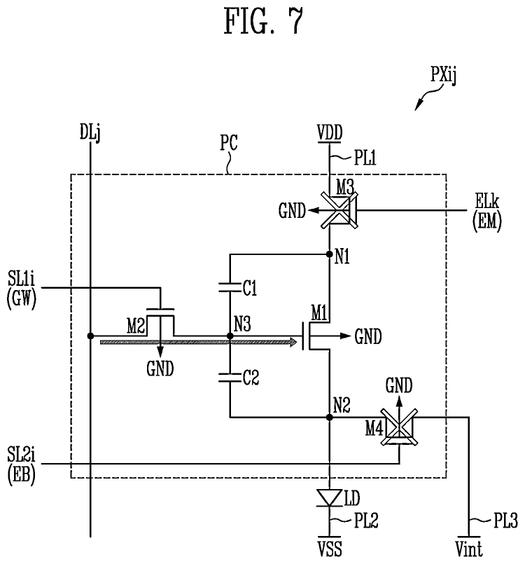

Referring to FIG. 7, during the second period T2, the second transistor M2 may be turned on by the first scan signal GW supplied to the i-th writing scan line SL1i. In addition, during the second period T2, the fourth transistor M4 may be turned off by the second scan signal EB supplied to the i-th initialization scan line SL2i. During the second period T2, the third transistor M3 may be maintained in a turned-off state by the emission control signal EM supplied to the emission control line ELk. During the second period T2, since the second transistor M2 is set to a turned-on state, the voltage Vdata of the data signal from the data line DLj may be supplied to the third node N3.

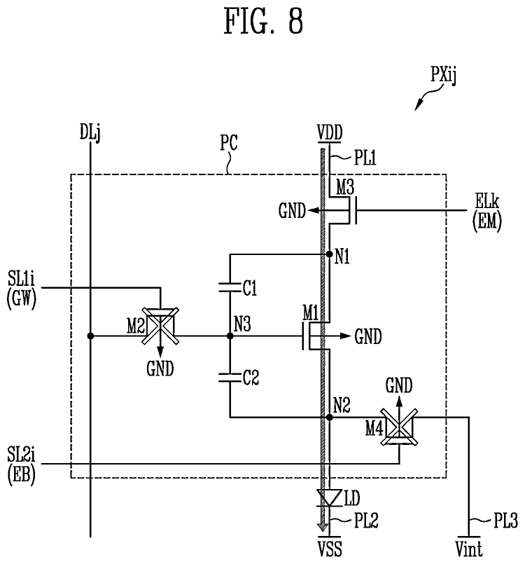

Referring to FIG. 8, during the third period T3, the second transistor M2 may be turned off by the first scan signal GW supplied to the i-th writing scan line SL1i. During the third period T3, the fourth transistor M4 may be maintained in a turned-off state by the second scan signal EB supplied to the i-th initialization scan line SL2i.

In addition, during the third period T3, the third transistor M3 may be turned on by the emission control signal EM supplied to the emission control line ELk. During the third period T3, since the third transistor M3 is set to a turned-on state, the first transistor (driving transistor) M1 may control the amount of current supplied from the first driving power source VDD to the second node N2 in response to a voltage applied to the third node N3.

According to embodiments of the present invention, a process in which the threshold voltage of the first transistor M1 is compensated by reflecting the difference in changes in a drain electrode N1 voltage and the source electrode N2 voltage of the first transistor M1 to a gate electrode N3 voltage of the first transistor M1 will be described in detail with reference to FIG. 8.

First, a voltage of the gate electrode N3 of the first transistor M1 calculated by reflecting the amount of voltage change at the first node N1 may be expressed based on Equation 1.

$$V N 3 = V N 1 + ΔV N 1 \times ( c 2 / c 1 + c 2 ) \qquad ( 1 )$$

Referring to Equation 1, VN3 may represent the voltage of the third node N3 in which the amount of voltage change at the first node N1 in the third period T3 is reflected. VN1 may be the voltage of the first node N1 in the third period T3. ΔVN1 may represent the amount of voltage change at the first node N1 in the second and third periods T2 and T3. c1 may be a capacitance value of the first capacitor C1. c2 may be a capacitance value of the second capacitor C2.

An equation in which the amount of voltage change at the second node N2 is reflected in a voltage VN3 of the gate electrode N3 of the first transistor M1, calculated by reflecting the amount of voltage change at the first node N1, may be expressed based on Equation 2.

$$V N {3}^{′} = V N 3 + ΔV N 2 \times ( c 1 / c 1 + c 2 ) \qquad ( 2 )$$

Referring to Equation 2, VN3′ may represent the voltage of the third node N3 in which the amount of voltage change at the first node N1 and the amount of voltage change at the second node N2 in the third period T3 are reflected. ΔVN2 may represent the amount of voltage change at the second node N2 in the second and third periods T2 and T3.

As shown in Equation 1 and Equation 2, a voltage level of the third node N3 in the third period T3 may be calculated by reflecting the amount of voltage change at the first node N1 and the amount of voltage change at the second node N2. Accordingly, even if the voltage of the first node N1 and the voltage of the second node N2 change during the second and third periods T2 and T3, the magnitude of the current flowing from the first node N1 to the second node N2 may be maintained constant.

According to an embodiment of the present invention, threshold voltage compensation may be independently performed for each of first transistors M1 included in the pixels PX of FIG. 2. For example, each of the pixels PX included in the pixel unit 110 of FIG. 2 may include the first transistor. In this case, when the display device 100 is driven, the first transistors M1 of the pixels PX may have different threshold voltages. In this case, the amount of voltage changes at the first and second nodes N1 and N2 of the pixels PX may also be set differently to correspond to the threshold voltages of respective ones of the first transistors. Since the amounts of voltage changes at the first and second nodes N1 and N2 may be reflected in the third node N3, a difference in the threshold voltages of the first transistors M1 included in the pixels PX can be compensated.

As described above, since the threshold voltage of the first transistor M1 operating as a driving transistor may be compensated by the third node N3, an effect of a change in the threshold voltage of the first transistor M1 on the current flowing through the first transistor M1 to the light emitting element LD can be minimized or at least reduced. Accordingly, the display device 100 may have improved grayscale expression.

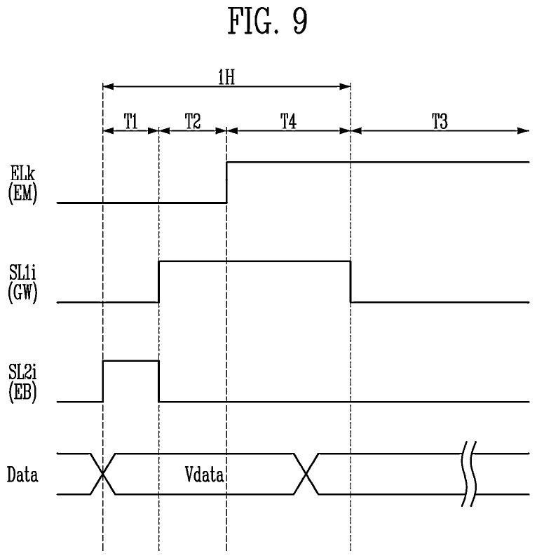

FIG. 9 is a waveform diagram illustrating an embodiment of the method for driving the pixel shown in FIG. 4.

Referring to FIGS. 2, 4, and 9, the horizontal period 1H (or specific horizontal period) in which the data signal is supplied to the pixel PXij located on the i-th horizontal line and the j-th vertical line may be divided into a first period T1, a second period T2, and a fourth period T4. The start time point of the fourth period T4 may be equal to or after the end time point of the second period T2. The end time point of the fourth period T4 may be equal to or before the start time point of the third period T3.

Hereinafter, since the first period T1, the second period T2, and the third period T3 of FIG. 9 can be described similarly to the first period T1, the second period T2, and the third period T3 of FIG. 4, overlapping contents thereof will be briefly described or omitted.

The data driver 140 may supply the voltage Vdata of the data signal to the data line DLj during the first period T1 to the third period T3.

The scan driver 130 (or the first scan driver 132) may supply the first scan signal GW to the i-th writing scan line SL1i during the second period T2 and the fourth period T4. The scan driver 130 (or the second scan driver 134) may supply the second scan signal EB to the i-th initialization scan line SL2i during the first period T1.

The emission driver 150 may supply the emission control signal EM to the emission control line ELk during the fourth period T4 and the third period T3. The fourth period T4 may be, for example, a period for securing a timing margin for a light emitting operation. By securing the fourth period T4, the light emitting element may stably emit light in the third period T3 even if a time delay occurs in a process of transmitting the signals EM, GW, and EB. In addition, reliability of the operation for compensating the threshold voltage of the first transistor M1 can be increased. The fourth period T4 may be referred to as a timing margin period. The length of the fourth period T4 is not limited to that shown in FIG. 9 and may vary depending, for example, on a user setting.

The second transistor M2 may be maintained in a turned-on state by the first scan signal GW supplied to the i-th writing scan line SL1i during the fourth period T4. In addition, the third transistor M3 may be turned on by the emission control signal EM supplied to the emission control line ELk during the fourth period T4.

In addition, the fourth transistor M4 may be maintained in a turned-off state by the second scan signal EB supplied to the i-th initialization scan line SL2i during the fourth period T4.

Because the third transistor M3 is turned on, during the fourth period T4, the light emitting element LD may emit a small amount of light with luminance corresponding to the amount of current supplied from the first transistor M1.

According to the pixel and the display device including the same according to the embodiments of the present invention, the pixel can be implemented using a transistor (for example, MOSFET) suitable for a high resolution display panel.

However, effects of the present invention are not limited to the above-described effects, and may be variously extended without departing from the spirit and scope of the present invention.

Although the technical spirit of the present invention has been specifically described according to the above-described embodiments, it should be noted that the above-described embodiments are intended to illustrate the present invention and not to limit the scope of the present invention. Those of ordinary skill in the art to which the present invention pertains will understand that various modifications are possible within the scope of the technical spirit of the present invention.

Therefore, the technical protection scope of the present invention is not limited to the detailed description described in the specification, but should be determined by the appended claims. In addition, all changes or modifications derived from the meaning and scope of the claims and their equivalents should be construed as being included in the scope of the present invention. The embodiments may be combined to form additional embodiments.

What is claimed is:

1. A pixel comprising:
a first transistor having a first electrode connected to a first node, a second electrode connected to a second node, and a gate electrode connected to a third node;
a second transistor connected between a data line and the third node and having a gate electrode electrically connected to a first scan line;
a third transistor connected between a first power source line and the first node, and having a gate electrode electrically connected to an emission control line, the first power source line being a line to which a voltage of a first driving power source is supplied;
a first capacitor connected between the first node and the third node;
a second capacitor connected between the second node and the third node; and
a light emitting element connected between the second node and a second power source line to which a second driving power source is supplied.

2. The pixel of claim 1, further comprising:
a fourth transistor having a first electrode connected to the second node, a second electrode electrically connected to a third power source line to which an initialization power source is supplied, and a gate electrode electrically connected to a second scan line.

3. The pixel of claim 2, wherein the light emitting element is configured to be turned off when a voltage of the initialization power source is supplied to the second node.

4. The pixel of claim 2, wherein each of the first to fourth transistors is a MOSFET including a body electrode.

5. The pixel of claim 4, wherein each of the first to fourth transistors is an N-type transistor.

6. The pixel of claim 4, wherein a ground voltage is supplied to the body electrode of each of the first to fourth transistors.

7. The pixel of claim 2, wherein one horizontal period includes a first period and a second period,
wherein, during the first period, the fourth transistor is configured to be set to a turned-on state, and the second and third transistor are configured to be set to a turned-off state, and
wherein, during the second period after the first period, the second transistor is configured to be set to a turned-on state, and the third and fourth transistors are configured to be set to a turned-off state.

8. The pixel of claim 7, wherein a voltage of a data signal is supplied to the data line during the first and second periods.

9. The pixel of claim 7, wherein the horizontal period further includes a third period, and
wherein, during the third period after the second period, the second and third transistors are configured to be set in a turned-on state and the fourth transistor is configured to be set to the turned-off state.

10. A display device comprising:
pixels connected to writing scan lines, initialization scan lines, data lines, and emission control lines, wherein a pixel located in an i-th pixel row (i is an integer greater than 0) and a j-th pixel column (j is an integer greater than 0) includes:
a first transistor having a first electrode connected to a first node, a second electrode connected to a second node, and a gate electrode connected to a third node;
a second transistor connected between a j-th data line among the data lines and the third node, and configured to be turned on when a first scan signal is supplied to a first scan line among the writing scan lines;
a third transistor connected between a first power source line to which a voltage of a first driving power source is supplied and the first node, and configured to be turned on when an emission control signal is supplied to a k-th emission control line (k is an integer greater than 0);
a first capacitor connected between the first node and the third node;
a second capacitor connected between the second node and the third node; and
a light emitting element connected between the second node and a second power source line to which a second driving power source is supplied.

11. The display device of claim 10, wherein the pixel located in the i-th pixel row and the j-th pixel column further includes:
a fourth transistor having a first electrode connected to the second node, a second electrode electrically connected to a third power source line to which an initialization power source is supplied, and configured to be turned on when a second scan signal is supplied to a second scan line.

12. The display device of claim 11, wherein each of the first to fourth transistors is a MOSFET including a body electrode, and a ground voltage is supplied to the body electrode.

13. The display device of claim 11, wherein each of the first to fourth transistors is an N-type transistor.

14. A pixel, comprising:
a driving transistor connected between first and second nodes;
a first capacitor electrically connected between the first node and a gate of the driving transistor;
a second capacitor electrically connected between the second node and the gate of the driving transistor, wherein:
the gate of the driving transistor is coupled to a third node connected between the first capacitor and the second capacitor,
the first capacitor is configured to transmit an amount of voltage change at the first node to the third node, and
the second capacitor is configured to transmit an amount of voltage change at the second node to the third node.

15. The pixel of claim 14, wherein the driving transistor includes a body electrode.

16. The pixel of claim 15, wherein:
the amount of voltage change at the first node corresponds to a difference in voltage of the first node that takes place between a data signal writing period of the pixel and an emission period of the pixel, and
the amount of voltage change at the second node corresponds to a difference in voltage of the second node that takes place between the data signal writing period and the emission period of the pixel.

17. The pixel of claim 16, wherein a voltage of the third node is compensated by the voltage change at the first node and the voltage change at the second node to maintain flow of a constant current from the first node to the second node during the signal writing period and the emission period of the pixel.

18. The pixel of claim 15, wherein the body electrode is coupled to a ground voltage.

19. The pixel of claim 14, further comprising:
an emission transistor connected to the first node, and
an initialization transistor connected to the second node,
wherein each of the emission transistor and the initialization transistor includes a body electrode.

20. The pixel of claim 19, wherein:
the emission transistor is connected to a first voltage source, and
the initialization transistor is coupled to a second voltage source.
